(19) United States
(12) Patent Application Publication
(10) Pub. No.: US 2016/0065122 A1
(43) Pub. Date: Mar. 3, 2016

(54) EXPANDABLE STICKING SOLAR CELL APPARATUS AND POWER SUPPLY THEREOF

(71) Applicant: KAO YU HSIN INTERNATION CO.,LED, Kaohsiung (TW)

(72) Inventor: SHIH-YEN CHEN, Kaohsiung (TW)

(21) Appl. No.: 14/468,761

(22) Filed: Aug. 26, 2014

(51) Int. Cl. H02S 30/10; H01L 31/048

(52) U.S. Cl. CPC H02S 30/10; H01L 31/048

(57) ABSTRACT

An expandable sticking solar cell apparatus includes a solar cell module, a frame protective cover, four connectors, a double-sided adhesive and four conductive wires. The frame protective cover includes a housing space to hold the solar cell module and four lateral side walls and a bottom wall to form the housing space. The four connectors are located respectively on the four lateral side walls. The solar cell module has positive and negative electrodes that are electrically connected to the four connectors through the four conductive wires. The double-sided adhesive is located on the bottom wall of the frame protective cover, through which multiple solar cell apparatus can be fixedly mounted onto a substrate in varying array fashions. The solar cell apparatus form electrical connection via parallel or serial connection through the connectors to increase voltage or current, thus can suit dimension and specification alterations of different electronic products.

### FIELD OF THE INVENTION

The present invention relates to a solar cell apparatus and particularly to a solar cell apparatus that is expandable to increase voltage or current.

### BACKGROUND OF THE INVENTION

In recent years electronic products such as mobile phones, tablet computers, digital cameras, digital watches and the like have been developed rapidly. To protect these electronic products a protective cover often is required to avoid them from being impacted or scraped by external forces. To meet personalization requirements the protective cover is designed and made in varying profiles. At present the protective cover merely provides functions of decoration and protecting the electronic products from being impacted or scraped. In order to increase the functions of the protective cover, a technique of adding solar cells thereon has been developed and introduced to provide charging of the electronic products. The solar cells have the advantage of independent charge upon receiving projection from sunshine or lighting facilities, hence are mainly used in outdoors where no other charge facility is available, or when power grid fails due to natural disasters.

FIG. 1 illustrates Taiwan new utility patent No. M421594 entitled “Protective cover equipped with thin film solar cells” which provides a technique to add solar cells onto a protective cover used on an electronic product. It disclosed a equipped with thin film solar cells. The protective cover 1 includes a device cover 2 which has an opening 3, a housing space 5 to house a portable electronic device 4, and flexible thin film solar cells 6 located on the device cover 2. The flexible thin film solar cells 6 have flexible physical characteristics, hence can remain intact even subject to abnormal external force and deformed in profile.

The solar cells adopted the aforesaid conventional technique are a product of a fixed specification, i.e., their dimensions, voltage and current are constant. However, different electronic products require different voltages and currents, and have to be customized. These days electronic products have rapid generation change. To make solar cells in a made-to-order fashion for different electronic products is difficult to increase mass production scale, this also makes reducing the production cost difficult, hence cannot meet the requirement of lowering the cost.

In other words, although the conventional protective cover for the electronic products can be attached with solar cells, the product dimensional specifications are changed frequently due to rapid development of the electronic products, consequentially the dimension of the protective cover also has to be changed. This causes the protective cover equipped with solar cells has to be remade and results in a higher cost. As a result, consumer's purchase desire is lower, and promotion of the products is less effective.

### SUMMARY OF THE INVENTION

The primary object of the present invention is to provide an expandable sticking solar cell apparatus that has easy expansion characteristic and can be expanded and changed with rapid alteration of product dimensions of electronic products, and can increase voltage and current according to actual requirements to meet charge requirements of different electronic products. It also adopts modular design and can be mass produced in a large scale to reduce cost to meet requirements.

The expandable sticking solar cell apparatus according to the invention includes a solar cell module, a frame protective cover, four connectors, a double-sided adhesive and four conductive wires. The frame protective cover is formed in a square and includes a housing space to hold the solar cell module and four lateral side walls and a bottom wall to form the housing space. The four connectors are located respectively on the four lateral side walls. The solar cell module has positive and negative electrodes that are electrically connected to the four connectors through the four conductive wires. The double-sided adhesive is located on the bottom wall of the frame protective cover.

Thus, multiple the solar cell apparatus of the invention can be fixedly mounted onto a substrate through the double-sided adhesive in an array fashion. Different solar cell apparatus can be electrically connected in series or in parallel through the four connectors, or disconnected with each other to adjust voltage or current and provide an output voltage. It can be changed according to the dimensions and specifications of electronic products. Namely, the solar cell apparatus of the invention provides expandability. It also adopts a modular design suitable for mass production in a large scale to reduce the cost.

The foregoing, as well as additional objects, features and advantages of the invention will be more readily apparent from the following detailed description, which proceeds with reference to the accompanying drawings.

### BRIEF DESCRIPTION OF THE DRAWINGS

FIG. 1 is a perspective view of a conventional protective cover equipped with thin film solar cells.

FIG. 2 is a perspective view of the solar cell apparatus of the invention.

FIG. 3 is a perspective view of a modularized solar cell apparatus of the invention at a disassembly condition.

FIG. 4 is an exploded view of the solar cell apparatus of the invention.

FIG. 5 is a perspective view of the solar cell apparatus of the invention implemented in a single unit.

FIG. 6 is a perspective view of the solar cell apparatus of the invention implemented in a single row.

FIG. 7 is a perspective view of the solar cell apparatus of the invention implemented in a single column.

FIG. 8 is a perspective view of the solar cell apparatus of the invention implemented in an array fashion.

FIG. 9 is a block diagram of an electric structure of the solar cell apparatus of the invention.

FIG. 10 is a block diagram of another electric structure of the solar cell apparatus of the invention.

FIG. 11 is a block diagram of the invention showing an electric structure of the solar cell apparatus incorporated with an electrical power storage device.

FIG. 12 is a block diagram of the invention showing another electric structure of the solar cell apparatus incorporated with an electrical power storage device.

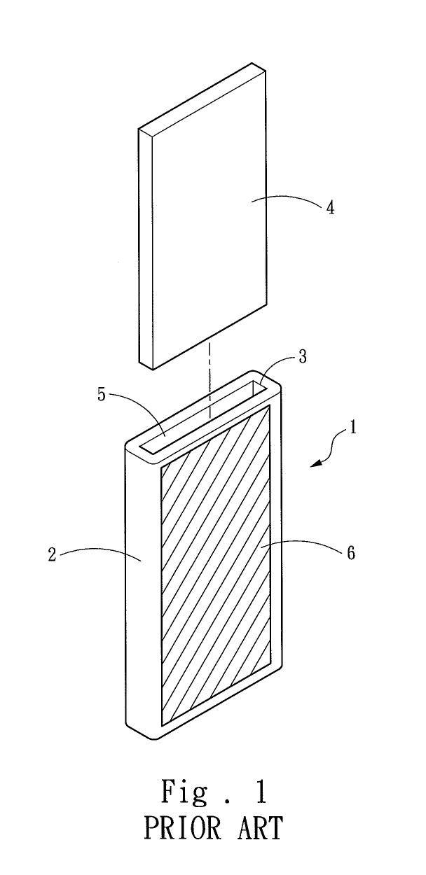

### DETAILED DESCRIPTION OF THE PREFERRED EMBODIMENTS

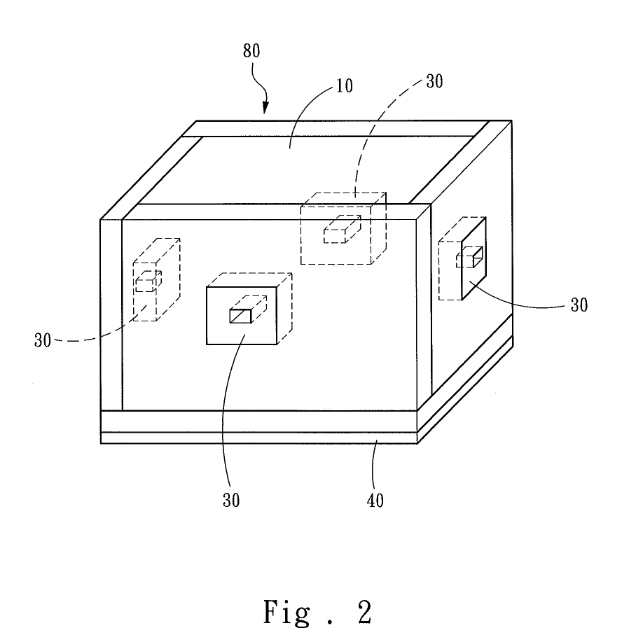

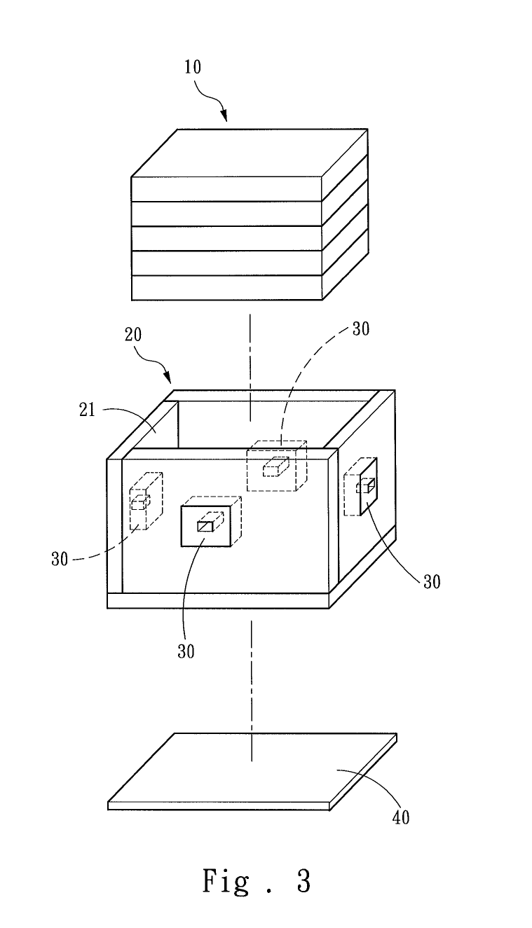

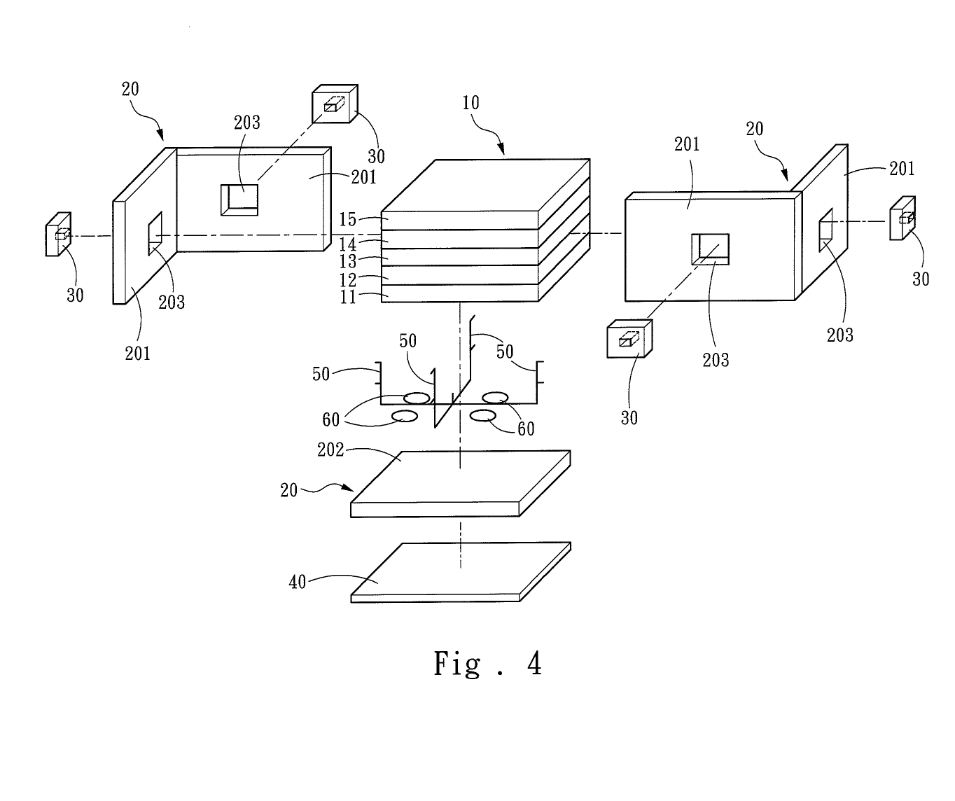

Please referring to FIGS. 2, 3 and 4, the present invention aims to provide an expandable sticking solar cell apparatus 80 which includes a solar cell module 10, a frame protective cover 20, four connectors 30, a double-sided adhesive 40 and four conductive wires 50. The frame protective cover 20 is formed in a square and includes a housing space 21 to hold the solar cell module 10 and four lateral side walls 201 and a bottom wall 202 to form the housing space 21. The four connectors 30 are located respectively on the four lateral side walls 201. The double-sided adhesive 40 is located on the bottom wall 202 of the frame protective cover 20. The solar cell module 10 has positive and negative electrodes that are electrically connected to the four connectors 30 through the four conductive wires 50.

The solar cell module 10 consists of, in this order, a transparent material 11, a copolymer of ethylene and vinyl acetate 12, a solar cell 13, another copolymer of ethylene and vinyl acetate 14, and another transparent material 15. The solar cell 13 is selected from the group consisting of monocrystalline silicon solar cell, polycrystalline silicon solar cell, amorphous silicon solar cell, cadmium telluride solar cell, copper indium selenide solar cell, copper indium gallium selenide solar cell, gallium arsenide solar cell, photochemical solar cell, photosensitive dye solar cell, polymer solar cell, and nano-crystals solar cell. The two transparent materials 11 and 15 are selected from either of glass material or plastic material. The frame protective cover 20 is made from material selected from the group consisting of plastics, rubber, silicone, metal or alloy.

The four lateral side walls 201 of the frame protective cover 20 can have respectively an opening 203 to hold one of the four connectors 30. The bottom wall 202 of the frame protective cover 20 and the bottom of the solar cell module 10 can have respectively four magnets 60 located thereon to provide magnetic forces for attraction and anchoring. Anyone of the four connectors 30 can be electrically connected to the positive and negative electrodes of the solar cell module 10 through anyone of the four conductive wires 50, and also can be connected to the rest three connectors 30 through the rest three conductive wires 50. Namely, one connector 30 can be electrically connected to the positive and negative electrodes of the solar cell module 10, and also electrically connected at the same time to the connectors 30 of the solar cell module 10, and then electrically connected to the rest three connectors 30 through the rest three conductive wires 50.

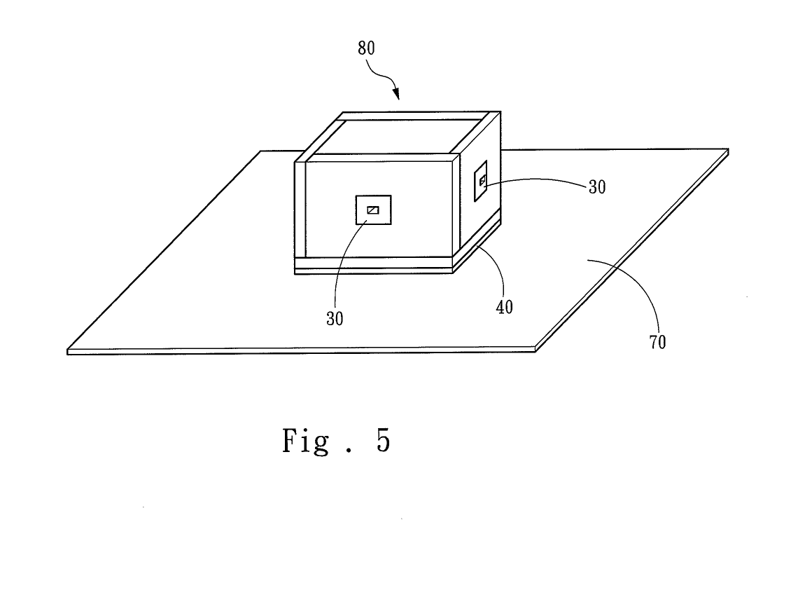

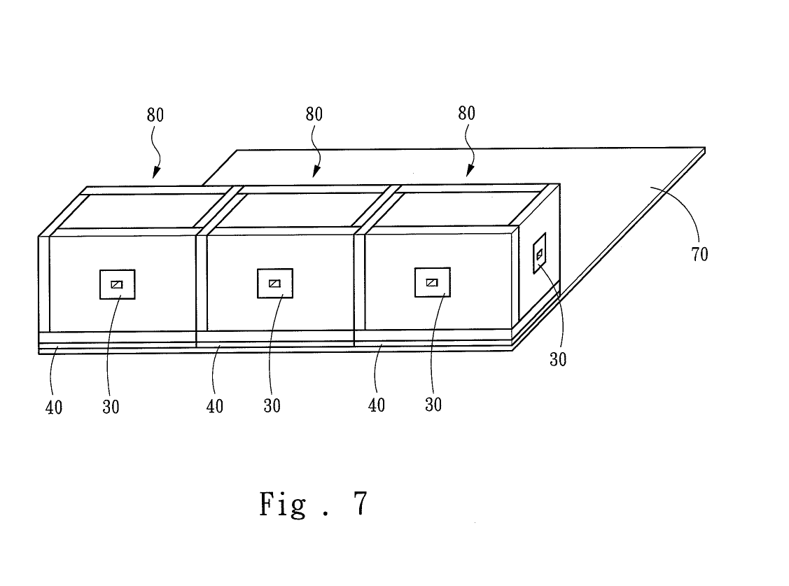

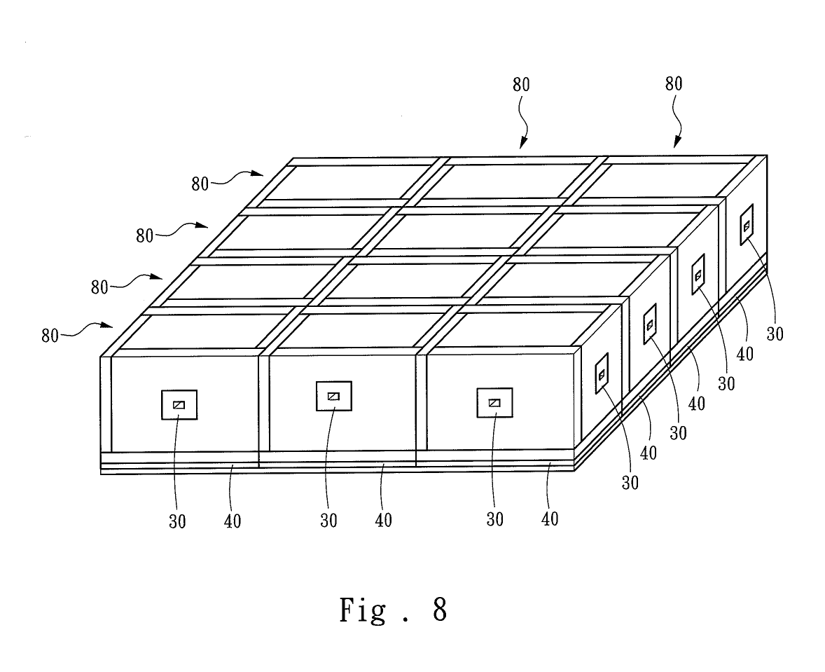

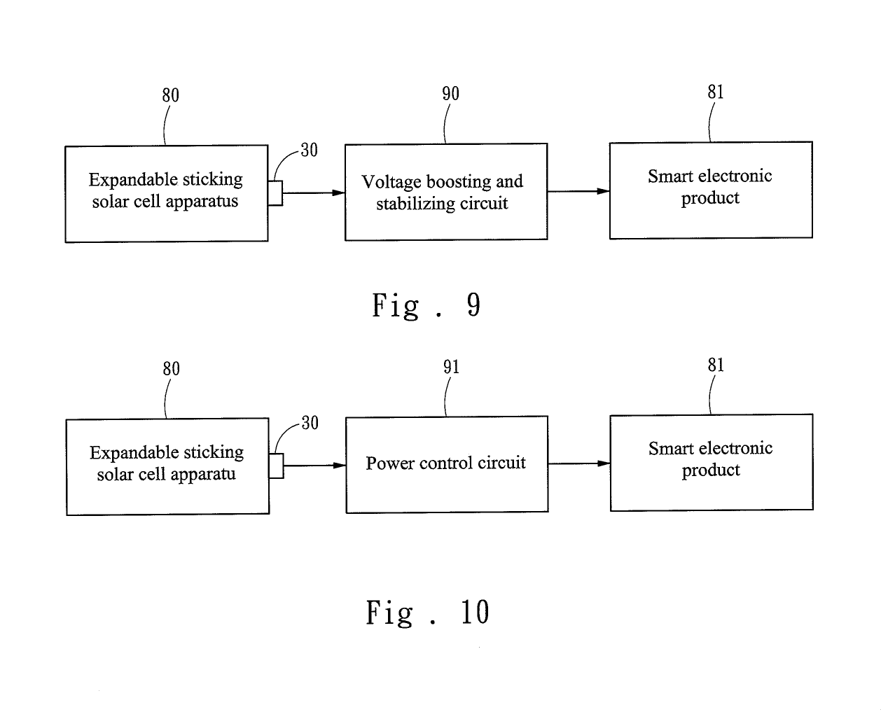

Please refer to FIGS. 5 through 8, when the expandable sticking solar cell apparatus 80 of the invention is in use it includes multiple sets to make a power supply to charge an electronic product 81 (as shown in FIG. 9). The power supply includes a substrate 70 and a plurality of the expandable sticking solar cell apparatus 80. The multiple expandable sticking solar cell apparatus 80 are arranged in an array fashion and fixedly bonded to the substrate 70 via the double-sided adhesive 40. The abutting multiple expandable sticking solar cell apparatus 80 can be selectively connected in parallel, in series, or disconnected. The expandable sticking solar cell apparatus 80 generate an output voltage to charge the electronic product 81.

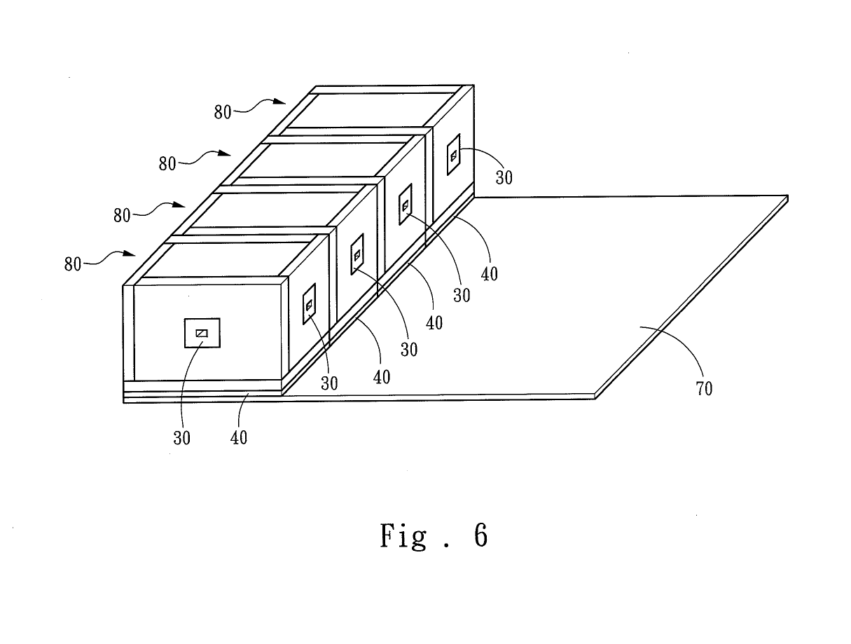

Hence the expandable sticking solar cell apparatus 80 can be easily bonded the substrate 70 to form a desired array pattern as shown in FIGS. 6, 7 and 8. The multiple expandable sticking solar cell apparatus 80 are connected through the connectors 30. The connectors 30 can be connected in three types of parallel, series and open circuit so that the connectors 30 can be selectively connected via any fashion among the parallel, series and open circuit to generate the output voltage.

Please refer to FIGS. 9 and 10 for the block diagrams of electrical structure of the soar cell apparatus of the invention. Two examples are provided. In the first example, after the expandable sticking solar cell apparatus 80 have been arranged in a required array, one of the connectors 30 is connected to a voltage boosting and stabilizing power circuit 90, i.e., the selected connector 30 is electrically connected to the electronic product 81 via the voltage boosting and stabilizing power circuit 90, hence can increase the voltage required by the electronic product 81 to provide charging.

In the second example, after the expandable sticking solar cell apparatus 80 have been arranged in a required array, one of the connectors 30 is connected to a power control circuit 91, i.e., the selected connector 30 is electrically connected to the electronic product 81 via the power control circuit 91, hence can supply a stable voltage to provide charging. The electronic product 81 can be selected from the group consisting of mobile phones, tablet computers, personal computers, notebook computers, smart watches, mobile power banks and portable audio devices, or other electronic products that require power supply and protection. The substrate 70 can be selected from the group consisting of silicone, rubber, metal, plastics, woven fabrics, alloy, leather, ceramics, fibers, cement, waterproof paper and wood that can form the protective cover to house the electronic product 81.

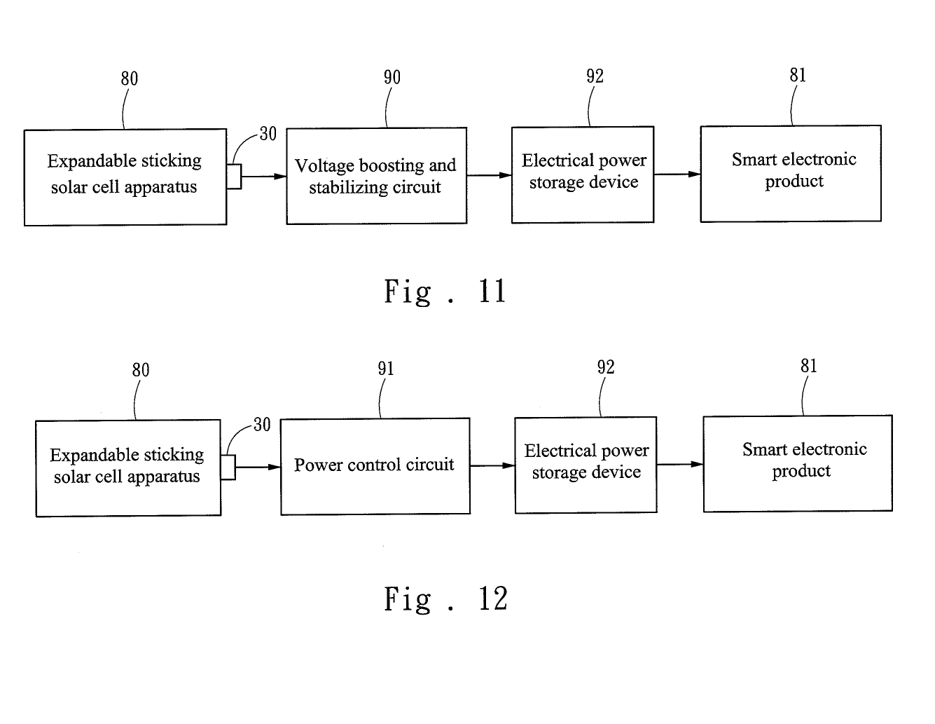

Please refer to FIGS. 11 and 12 for the block diagrams of electrical structure of the expandable sticking solar cell apparatus 80 of the invention incorporating with an electrical power storage device 92. Two types of electrical structure block diagrams are provided. In the first example, after the expandable sticking solar cell apparatus 80 have been arranged in a required array, one of the connectors 30 is connected to a voltage boosting and stabilizing power circuit 90, then connected to the electrical power storage device 92, i.e., the selected connector 30 is electrically connected to the electrical power storage device 92 via the voltage boosting and stabilizing power circuit 90 to charge the electrical power storage device 92, then the electrical power storage device 92 charges the electronic product 81.

In the second example, after the expandable sticking solar cell apparatus 80 have been arranged in a required array, one of the connectors 30 is connected to a power control circuit 91, then connected to the electrical power storage device 92, i.e., the selected connector 30 is electrically connected to the electrical power storage device 92 via the power control circuit 91 to supply a stable voltage to charge the electrical power storage device 92.

What is claimed is:

1. An expandable sticking solar cell apparatus, comprising:
a solar cell module;
a frame protective cover which is formed in a square and includes a housing space to hold the solar cell module and four lateral side walls and a bottom wall to form the housing space;
four connectors located respectively on the four lateral side walls;
a double-sided adhesive located on the bottom wall of the frame protective cover; and
four conductive wires to electrically connect positive and negative electrodes of the solar cell module with the four connectors.

2. The expandable sticking solar cell apparatus of claim 1, wherein the solar cell module is formed by arranging sequentially a transparent material, a copolymer of ethylene and vinyl acetate, a solar cell, another copolymer of ethylene and vinyl acetate, and another transparent material.

3. The expandable sticking solar cell apparatus of claim 2, wherein the solar cell is selected from the group consisting of monocrystalline silicon solar cell, polycrystalline silicon solar cell, amorphous silicon solar cell, cadmium telluride solar cell, copper indium selenide solar cell, copper indium gallium selenide solar cell, gallium arsenide solar cell, photochemical solar cell, photosensitive dye solar cell, polymer solar cell, and nano-crystals solar cell.

4. The expandable sticking solar cell apparatus of claim 2, wherein the two transparent materials are selected from the group consisting of glass material and plastic material.

5. The expandable sticking solar cell apparatus of claim 1, wherein the frame protective cover is made from material selected from the group consisting of plastics, rubber, silicone, metal and alloy.

6. The expandable sticking solar cell apparatus of claim 1, wherein the four lateral side walls of the frame protective cover include respectively an opening to hold one of the four connectors.

7. The expandable sticking solar cell apparatus of claim 1, wherein the bottom wall of the frame protective cover and a bottom of the solar cell module include respectively four magnets.

8. The expandable sticking solar cell apparatus of claim 1, wherein anyone of the four connectors is electrically connected to the positive and negative electrodes of the solar cell module through anyone of the four conductive wires, and connected to the rest three connectors through the rest three conductive wire.

9. A power supply to charge an electronic product, comprising:
a substrate; and
a plurality of expandable sticking solar cell apparatus of claim 1 that are arranged in an array fashion and fixedly bonded to the substrate through the double-side adhesive, the abutting expandable sticking solar cell apparatus being selectively coupled in parallel, coupled in series or disconnected with each other such as to generate an output voltage to charge the electronic product through anyone of the connectors.

10. The power supply of claim 9 further including a voltage boosting and stabilizing circuit, the connector being electrically connected to the electronic product through the voltage boosting and stabilizing circuit.

11. The power supply of claim 9 further including a power control circuit, the connector being electrically connected to the electronic product through the power control circuit.

12. The power supply of claim 9, wherein the substrate is selected from the group consisting of silicone, rubber, metal, plastics, woven fabrics, alloy, leather, ceramics, fibers, cement, waterproof paper and wood.

13. The power supply of claim 9, wherein the electronic product is selected from the group consisting of mobile phones, tablet computers, personal computers, notebook computers, smart watches, mobile power banks and portable audio devices.

14. The power supply of claim 9 further including an electrical power storage device which is electrically connected to the expandable sticking solar cell apparatus through the connector to charge the electronic product.

15. The power supply of claim 14 further including a voltage boosting and stabilizing circuit, the connector being electrically connected to the electrical power storage device through the voltage boosting and stabilizing circuit.

16. The power supply of claim 14 further including a power control circuit, the connector being electrically connected to the electrical power storage device through the power control circuit.
